(19) United States
(12) Patent Application Publication
(10) Pub. No.: US 2024/0145229 A1
(43) Pub. Date: May 2, 2024

(54) SILICON CARBIDE SUBSTRATE AND METHOD OF MANUFACTURING SILICON CARBIDE SUBSTRATE

(71) Applicant: SUMITOMO ELECTRIC INDUSTRIES, LTD., Osaka (JP)

(72) Inventors: Kyoko OKITA, Osaka (JP); Tsubasa HONKE, Osaka (JP); Shunsaku UETA, Osaka (JP)

(73) Assignee: SUMITOMO ELECTRIC INDUSTRIES, LTD., Osaka (JP)

(21) Appl. No.: 18/280,207

(22) PCT Filed: Nov. 9, 2021
(86) PCT No.: PCT/JP2021/041174

§ 371 Date: Sep. 2, 2023

(30) Foreign Application Priority Data
Mar. 12, 2021 (JP) 2021-039843

(51) Int. Cl. H01L 21/02; H01L 29/34

(52) U.S. Cl. CPC H01L 21/02019; H01L 29/34; H01L 29/1608

(57) ABSTRACT

A silicon carbide substrate includes a first main surface, a second main surface, and an outer peripheral surface. When a defect, in the first main surface, observed using a mirror electron microscope while irradiating the first main surface with an ultraviolet ray is a first defect and a defect, in the first main surface, observed using molten potassium hydroxide is a second defect, a value obtained by dividing an area density of the first defect by an area density of the second defect is more than 0.9 and less than 1.2. The first defect consists of a first blind scratch, a first basal plane dislocation spaced apart from the first blind scratch, a second basal plane dislocation in contact with the first blind scratch, and a second blind scratch spaced apart from each of the first basal plane dislocation and the second basal plane dislocation.

### TECHNICAL FIELD

The present disclosure relates to a silicon carbide substrate and a method of manufacturing the silicon carbide substrate. This application claims priority based on Japanese Patent Application No. 2021-039843 filed on Mar. 12, 2021. The entire contents described in the Japanese Patent Application are incorporated herein by reference.

### BACKGROUND ART

Japanese Unexamined Patent Application Publication No. 2016-139685 (PTL 1) describes a monocrystalline silicon carbide substrate having a roughness Ra of 1 nm or less and having blind scratches.

### CITATION LIST

### Patent Literature

PTL 1: Japanese Unexamined Patent Application Publication No. 2016-139685

### SUMMARY OF INVENTION

A silicon carbide substrate according to an embodiment of the present disclosure includes a first main surface, a second main surface, and an outer peripheral surface. The second main surface is located opposite to the first main surface. The outer peripheral surface is contiguous to each of the first main surface and the second main surface. When a defect, in the first main surface, observed using a mirror electron microscope while irradiating the first main surface with an ultraviolet ray is a first defect and a defect, in the first main surface, observed using molten potassium hydroxide is a second defect, a value obtained by dividing an area density of the first defect by an area density of the second defect is more than 0.9 and less than 1.2. The first defect consists of a first blind scratch, a first basal plane dislocation spaced apart from the first blind scratch, a second basal plane dislocation in contact with the first blind scratch, and a second blind scratch spaced apart from each of the first basal plane dislocation and the second basal plane dislocation. The second defect consists of the first basal plane dislocation and the second basal plane dislocation.

A method of manufacturing a silicon carbide substrate according to an embodiment of the present disclosure includes the following steps. Chemical mechanical polishing is performed on a silicon carbide single-crystal substrate. The silicon carbide single-crystal substrate is etched using a solution under a temperature condition of 70° C. or higher. The solution contains an aqueous alkali solution.

### BRIEF DESCRIPTION OF THE DRAWINGS

FIG. 1 is a schematic plan view showing the structure of a silicon carbide substrate according to an embodiment of the present disclosure.

FIG. 2 is a schematic cross-sectional view taken along line II-II of FIG. 1.

FIG. 3 is an enlarged plan view of region III of FIG. 1.

FIG. 4 is a schematic cross-sectional view taken along line IV-IV of FIG. 3.

FIG. 5 is an enlarged plan view of region V of FIG. 1.

FIG. 6 is a schematic cross-sectional view taken along line VI-VI of FIG. 5.

FIG. 7 is an enlarged plan view of region VII of FIG. 1.

FIG. 8 is a schematic cross-sectional view taken along line VIII-VIII of FIG. 7.

FIG. 9 is an enlarged plan view of region IX of FIG. 1.

FIG. 10 is a schematic cross-sectional view taken along line X-X of FIG. 9.

FIG. 11 is an enlarged plan view of region XI of FIG. 1.

FIG. 12 is a schematic cross-sectional view taken along line XII-XII of FIG. 11.

FIG. 13 is an enlarged plan view of region XIII of FIG. 1.

FIG. 14 is a schematic cross-sectional view taken along line XIV-XIV of FIG. 13.

FIG. 15 is an enlarged plan view of region XV of FIG. 1.

FIG. 16 is a schematic cross-sectional view taken along line XVI-XVI of FIG. 15.

FIG. 17 is a schematic diagram showing a configuration of a mirror electron microscope.

FIG. 18 is a schematic diagram showing a place where a mirror electron image is taken.

FIG. 19 is a schematic diagram showing a mirror electron image of a second blind scratch.

FIG. 20 is a schematic diagram showing mirror electron images of the first dislocation and the third dislocation.

FIG. 21 is a schematic diagram showing a mirror electron image of a second dislocation.

FIG. 22 is a flow diagram schematically showing a method of manufacturing a silicon carbide substrate according to an embodiment of the present disclosure.

FIG. 23 is a schematic cross-sectional view showing a step of preparing a silicon carbide single-crystal substrate.

FIG. 24 is a schematic cross-sectional view showing the structure of the silicon carbide single-crystal substrate after the step of performing chemical mechanical polishing on the silicon carbide single-crystal substrate.

FIG. 25 is a schematic cross-sectional view showing a step of etching a silicon carbide single-crystal substrate using an aqueous alkali solution.

### DETAILED DESCRIPTION

### Problem to be Solved by the Present Disclosure

An object of the present disclosure is to provide a silicon carbide substrate capable of suppressing deterioration of surface roughness of a silicon carbide epitaxial layer and a method of manufacturing the silicon carbide substrate.

### Advantageous Effects of the Present Disclosure

According to the present disclosure, it is possible to provide a silicon carbide substrate capable of suppressing deterioration of surface roughness of a silicon carbide epitaxial layer, and a method of manufacturing the silicon carbide substrate.

### DESCRIPTION OF EMBODIMENTS

(1) A silicon carbide substrate according to an embodiment of the present disclosure includes a first main surface 1, a second main surface 2, and an outer peripheral surface 5. Second main surface 2 is located opposite to first main surface 1. Outer peripheral surface 5 is contiguous to each of first main surface 1 and second main surface 2. When a defect, in first main surface 1, observed using a mirror electron microscope while irradiating first main surface 1 with an ultraviolet ray is a first defect 81 and a defect, in first main surface 1, observed using molten potassium hydroxide is a second defect 82, a value obtained by dividing an area density of first defect 81 by an area density of second defect 82 is more than 0.9 and less than 1.2. First defect 81 consists of a first blind scratch 61, a first basal plane dislocation 10 spaced apart from first blind scratch 61, a second basal plane dislocation 20 in contact with first blind scratch 61, and a second blind scratch 62 spaced apart from each of first basal plane dislocation 10 and second basal plane dislocation 20. Second defect 82 consists of first basal plane dislocation 10 and second basal plane dislocation 20.
(2) In the silicon carbide substrate according to (1), the area density of first defect 81 may be determined under a condition that an interval between measurement regions in the first main surface 1 measured with the mirror electron microscope is 614 μm, and the measurement regions each have a square shape with each side of 80 μm.
(3) In the silicon carbide substrate according to (1) or (2), the area density of second defect 82 may be 1000/cm² or less.
(4) In the silicon carbide substrate according to (3), the area density of second defect 82 may be 500/cm² or less.
(5) In a silicon carbide substrate 100 according to any one of (1) to (4), the area density of first defect 81 may be 400/cm² or less.
(6) In silicon carbide substrate 100 according to any one of (1) to (5), a value obtained by dividing an area density of first blind scratch 61 and second blind scratch 62 by the area density of second defect 82 may be 0.6 or less.
(7) A method of manufacturing silicon carbide substrate 100 according to an embodiment of the present disclosure includes the following steps. Chemical mechanical polishing is performed on a silicon carbide single-crystal substrate 110. Silicon carbide single-crystal substrate 110 is etched using a solution under a temperature condition of 70° C. or higher. Solution 51 contains an aqueous alkali solution.
(8) In the method of manufacturing silicon carbide substrate 100 according to (7), the aqueous alkali solution may be an aqueous potassium hydroxide solution or an aqueous sodium hydroxide solution.
(9) In the method of manufacturing silicon carbide substrate 100 according to (7) or (8), the temperature condition may be 100° C. or lower.
(10) In the method of manufacturing silicon carbide substrate 100 according to any one of (7) to (9), solution 51 may further contain an oxidizing agent not causing an oxidation-reduction reaction with the aqueous alkali solution.
(11) In the method of manufacturing silicon carbide substrate 100 according to (10), the oxidizing agent may be a hydrogen peroxide solution.

### Details of Embodiments of the Present Disclosure

Hereinafter, embodiments of the present disclosure will be described with reference to the drawings. In the following drawings, the same or corresponding portions are denoted by the same reference numerals, and description thereof will not be repeated. Regarding crystallographic indications in the present specification, an individual orientation is represented by [ ], a group orientation is represented by < >, an individual plane is represented by ( ), and a group plane is represented by { }. Generally, a negative index is supposed to be crystallographically indicated by putting “-” (bar) above a numeral but is indicated by putting the negative sign before the numeral in the present specification.

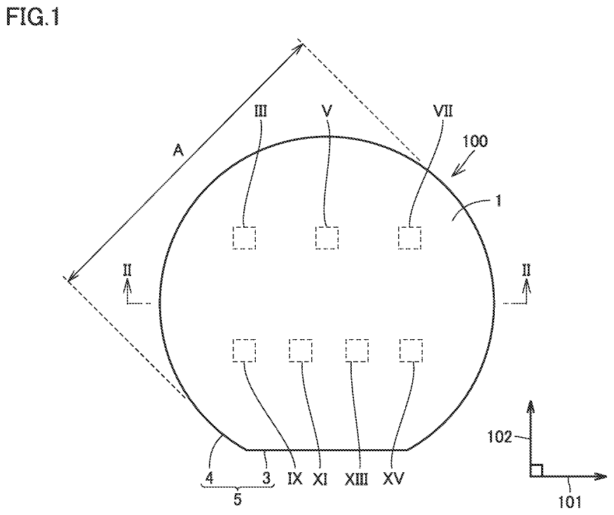

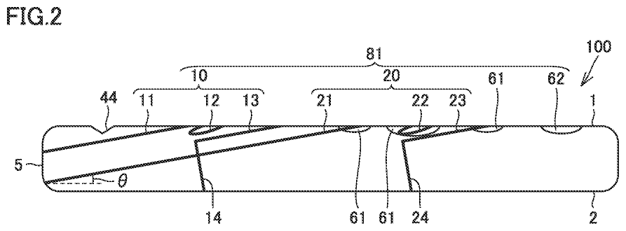

First, a configuration of a silicon carbide substrate 100 according to an embodiment of the present disclosure will be described. FIG. 1 is a schematic plan view illustrating the configuration of silicon carbide substrate 100 according to an embodiment of the present disclosure. FIG. 2 is a schematic cross-sectional view taken along line II-II of FIG. 1.

As shown in FIGS. 1 and 2, silicon carbide substrate 100 according to an embodiment of the present disclosure mainly has a first main surface 1, a second main surface 2, and an outer peripheral surface 5. As shown in FIG. 2, second main surface 2 is located opposite to first main surface 1. Outer peripheral surface 5 is contiguous to each of first main surface 1 and second main surface 2. Silicon carbide substrate 100 is composed of silicon carbide of polytype 4H. Silicon carbide substrate 100 contains an n-type impurity such as nitrogen (N). The conductivity type of silicon carbide substrate 100 is, for example, n-type. The concentration of the n-type impurity contained in silicon carbide substrate 100 is 1×10¹⁷ cm⁻³ to 1×10²⁰ cm⁻³, for example.

As shown in FIG. 1, a maximum diameter A of first main surface 1 is, for example, 150 mm or more (6 inches or more). Maximum diameter A of first main surface 1 may be, for example, 200 mm or more (8 inches or more). In this specification, 6 inches refers to 150 mm or 152.4 mm (25.4 mm×6). 8 inches refers to 200 mm or 203.2 mm (25.4 mm×8). Maximum diameter A of first main surface 1 is the maximum distance between any two points on outer peripheral surface 5 when viewed in a direction perpendicular to first main surface 1.

First main surface 1 is a surface inclined at an off-angle θ of more than 0° and 8° or less with respect to the {0001} plane, for example. Off-angle θ may be, for example, 10 or more or 2° or more. Off-angle θ may be 7° or less or may be 6° or less. Specifically, first main surface 1 may be a plane inclined at off-angle θ of more than 0° and 8° or less with respect to the (0001) plane. First main surface 1 may be a plane inclined at off-angle θ of more than 0° and 8° or less with respect to the (000-1) plane. The inclination direction (off direction) of first main surface 1 is, for example, a first direction 101.

As shown in FIG. 1, outer peripheral surface 5 may include, for example, an orientation flat 3 and an arc-shaped portion 4. Orientation flat 3 extends along first direction 101, for example. Arc-shaped portion 4 is contiguous to orientation flat 3. As shown in FIG. 1, when viewed in a direction perpendicular to first main surface 1, first main surface 1 extends along each of first direction 101 and a second direction 102. When viewed in a direction perpendicular to first main surface 1, first direction 101 is a direction perpendicular to second direction 102.

First direction 101 is, for example, the <11-20> direction. First direction 101 may be, for example, the [11-20] direction. First direction 101 may be a direction obtained by projecting the <11-20> direction onto first main surface 1. From another viewpoint, first direction 101 may be, for example, the <11-20> direction including a direction component.

Second direction 102 is, for example, the <1-100> direction. Second direction 102 may be, for example, the [1-100] direction. Second direction 102 may be a direction obtained by projecting the <1-100> direction onto first main surface 1, for example. From another viewpoint, second direction 102 may be, for example, the <1-100> direction including a direction component.

First main surface 1 is, for example, an epitaxial layer formation surface. In other words, a silicon carbide epitaxial layer (not shown) is provided on first main surface 1. Second main surface 2 is, for example, a drain electrode formation surface. In other words, a drain electrode (not shown) of a metal oxide semiconductor field effect transistor (MOSFET) is formed on second main surface 2.

As shown in FIG. 2, silicon carbide substrate 100 has, for example, a first defect 81 and a scratch 44. First defect 81 consists of a first basal plane dislocation 10, a second basal plane dislocation 20, a first blind scratch 61, and a second blind scratch 62. First basal plane dislocation 10 is spaced apart from each of first blind scratch 61 and second blind scratch 62. Second basal plane dislocation 20 extends to first blind scratch 61. Second basal plane dislocation 20 is spaced apart from second blind scratch 62. Second blind scratch 62 is spaced apart from each of first basal plane dislocation 10 and second basal plane dislocation 20.

First basal plane dislocation 10 includes, for example, a first dislocation 11, a second dislocation 12, and a third dislocation 13. First dislocation 11 is located on a basal plane. One end (first end) of first dislocation 11 is exposed to first main surface 1. The other end (second end) of first dislocation 11 is exposed to outer peripheral surface 5 or second main surface 2. Second dislocation 12 has a half-loop shape. Second dislocation 12 is located on a basal plane. Both ends of second dislocation 12 are exposed to first main surface 1. Third dislocation 13 is located on a basal plane. Third dislocation 13 is a basal plane dislocation extending to a first threading dislocation 14. One end (first end) of third dislocation 13 is exposed to first main surface 1. The other end (second end) of third dislocation 13 extends to first threading dislocation 14. First threading dislocation 14 is exposed on second main surface 2. First threading dislocation 14 is inclined with respect to third dislocation 13.

Second basal plane dislocation 20 includes, for example, a fourth dislocation 21, a fifth dislocation 22, and a sixth dislocation 23. Fourth dislocation 21 is located on a basal plane. One end (first end) of fourth dislocation 21 is exposed to first main surface 1. The other end (second end) of fourth dislocation 21 is exposed to outer peripheral surface 5 or second main surface 2. Fifth dislocation 22 has a half-loop shape. Fifth dislocation 22 is located on a basal plane. Both ends of fifth dislocation 22 are exposed to first main surface 1. Sixth dislocation 23 is located on a basal plane. Sixth dislocation 23 is a basal plane dislocation extending to a second threading dislocation 24. One end (first end) of sixth dislocation 23 is exposed to first main surface 1. The other end (second end) of sixth dislocation 23 extends to second threading dislocation 24. Second threading dislocation 24 is exposed on second main surface 2. Second threading dislocation 24 is inclined with respect to sixth dislocation 23.

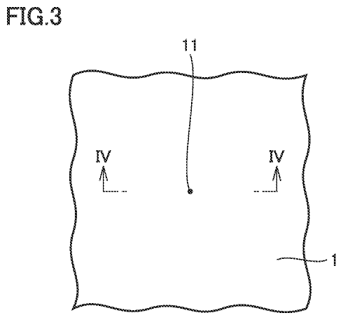

FIG. 3 is an enlarged plan view of region III of FIG. 1. As shown in FIG. 3, one end (first end) of first dislocation 11 is exposed on first main surface 1. When viewed in a direction perpendicular to first main surface 1, the shape of the end of first dislocation 11 is point-like.

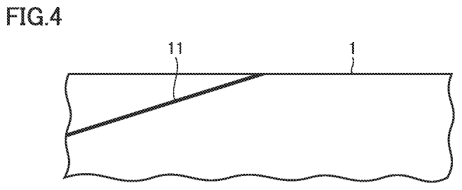

FIG. 4 is a schematic cross-sectional view taken along line IV-IV of FIG. 3. The cross section shown in FIG. 4 is perpendicular to first main surface 1. As shown in FIG. 4, first dislocation 11 extends along a basal plane.

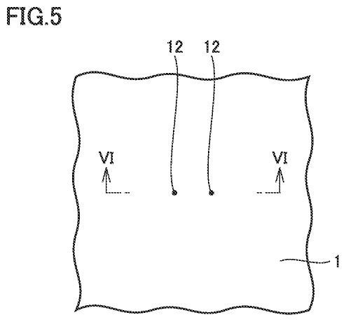

FIG. 5 is an enlarged plan view of region V of FIG. 1. As shown in FIG. 5, one end (first end) and the other end (second end) of second dislocation 12 are exposed on first main surface 1. When viewed in a direction perpendicular to first main surface 1, the shape of each of the two ends of second dislocation 12 is point-like.

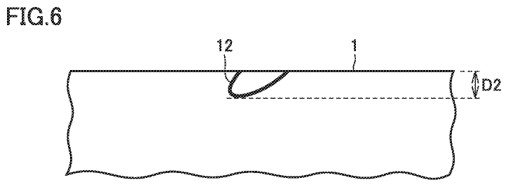

FIG. 6 is a schematic cross-sectional view taken along line VI-VI of FIG. 5. The cross section shown in FIG. 6 is perpendicular to first main surface 1. As shown in FIG. 6, the length of second dislocation 12 in the direction perpendicular to first main surface 1 is a fourth length D2. The lower limit of fourth length D2 is not particularly limited, and may be, for example, 0.1 nm or more, or may be 1 nm or more. The upper limit of fourth length D2 is not particularly limited, and may be, for example, 10 μm or less or 1 μm or less.

As shown in FIG. 2, silicon carbide substrate 100 includes first blind scratch 61 and second blind scratch 62. The blind scratches are polishing damages formed on silicon carbide substrate 100 in the polishing step. In each of first blind scratch 61 and second blind scratch 62, the silicon carbide crystal is distorted. Each of first blind scratch 61 and second blind scratch 62 is exposed to first main surface 1.

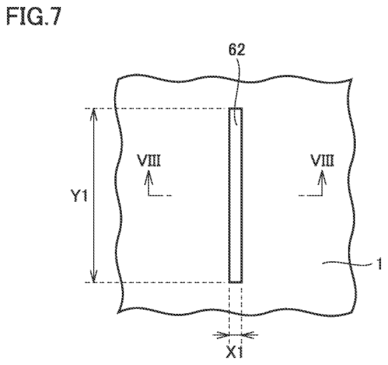

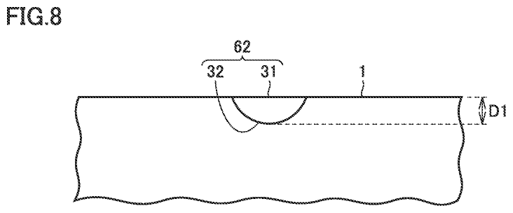

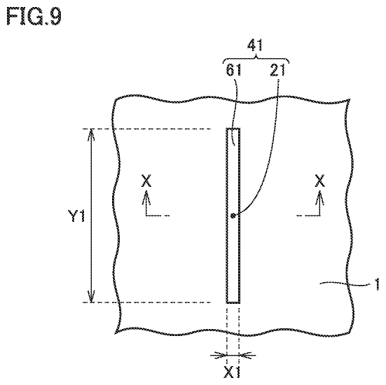

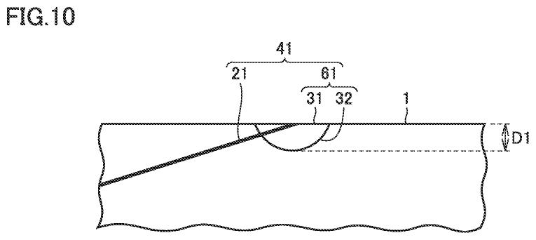

FIG. 7 is an enlarged plan view of region VII of FIG. 1. FIG. 8 is a schematic cross-sectional view taken along line VIII-VIII of FIG. 7. FIG. 9 is an enlarged plan view of region IX of FIG. 1. FIG. 10 is a schematic cross-sectional view taken along line X-X of FIG. 9.

As shown in FIGS. 7 and 9, when viewed in a direction perpendicular to first main surface 1, each of first blind scratch 61 and second blind scratch 62 extends linearly. In other words, when viewed in a direction perpendicular to first main surface 1, each of first blind scratch 61 and second blind scratch 62 has a linear shape. The linear shape may be a straight line shape or a curved line shape. As shown in FIGS. 7 and 9, when viewed in the direction perpendicular to first main surface 1, the length (a first length Y1) of each of first blind scratch 61 and second blind scratch 62 in the longitudinal direction is, for example, 10 μm or more. When the blind scratch is curved, the length of the blind scratch in the longitudinal direction (first length Y1) is a length obtained by extending the curved blind scratch in a straight line. The direction in which the blind scratches extend may be first direction 101, second direction 102, or a direction inclined with respect to each of first direction 101 and second direction 102. When the blind scratches are curved, the direction in which the blind scratches extend is the tangential direction of the blind scratches. The direction in which the blind scratches extend is not particularly limited.

As shown in FIGS. 7 and 9, when viewed in the direction perpendicular to first main surface 1, the lower limit of the length of the blind scratch in the longitudinal direction (first length Y1) is not particularly limited, but may be, for example, 5 times or more or 10 times or more the width of the blind scratch in the lateral direction (a first width X1). When viewed in the direction perpendicular to first main surface 1, the upper limit of the length of the blind scratch in the longitudinal direction (first length Y1) is not particularly limited, but may be, for example, 1000 times or less or 500 times or less the width of the blind scratch in the lateral direction (first width X1).

The cross-section shown in FIG. 8 is perpendicular to first main surface 1. Second blind scratch 62 has a bottom surface 32 and an upper surface 31. Bottom surface 32 is contiguous to upper surface 31. First main surface 1 includes upper surface 31. Upper surface 31 constitutes a part of first main surface 1. Bottom surface 32 is located inside silicon carbide substrate 100. In a direction perpendicular to first main surface 1, bottom surface 32 may be located between first main surface 1 and second main surface 2.

The cross-section shown in FIG. 10 is perpendicular to first main surface 1. Fourth dislocation 21 penetrates through bottom surface 32 of first blind scratch 61. Fourth dislocation 21 is exposed on upper surface 31 of first blind scratch 61. In other words, fourth dislocation 21 is in contact with each of upper surface 31 and bottom surface 32. Fourth dislocation 21 is stuck into first blind scratch 61.

As shown in FIG. 10, most of fourth dislocation 21 is located outside first blind scratch 61. As shown in FIG. 10, in the direction parallel to the basal plane, the length of the portion of fourth dislocation 21 located outside first blind scratch 61 is longer than the length of the portion of fourth dislocation 21 located inside first blind scratch 61. As shown in FIG. 9, when viewed in the direction perpendicular to first main surface 1, the end portion of fourth dislocation 21 exposed to first main surface 1 may be surrounded by the outer edge of first blind scratch 61.

As shown in FIGS. 8 and 10, the thickness of each of first blind scratch 61 and second blind scratch 62 in the direction perpendicular to first main surface 1 is a first thickness D1. The lower limit of first thickness D1 is not particularly limited, and may be, for example, 0.1 nm or more or 1 nm or more. The upper limit of first thickness D1 is not particularly limited, and may be, for example, 1000 nm or less or 100 nm or less.

As shown in FIG. 9, first blind scratch 61 into which fourth dislocation 21 is stuck constitutes a first region 41. First region 41 constitutes a part of first main surface 1. First region 41 includes fourth dislocation 21 exposed on first main surface 1 and upper surface 31 of first blind scratch 61.

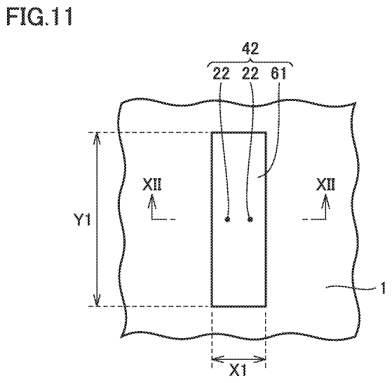

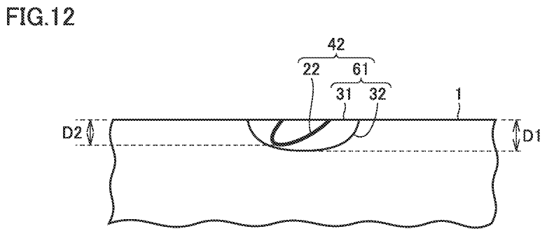

FIG. 11 is an enlarged plan view of region XI of FIG. 1. FIG. 12 is a schematic cross-sectional view taken along line XII-XII of FIG. 11. The cross-section shown in FIG. 12 is perpendicular to first main surface 1. In a cross-sectional view, fifth dislocation 22 has a half-loop shape. At least a portion of fifth dislocation 22 is located inside first blind scratch 61. The whole of fifth dislocation 22 may be located inside first blind scratch 61. Fifth dislocation 22 is spaced apart from each of second main surface 2 and outer peripheral surface 5.

As shown in FIG. 12, fifth dislocation 22 may be spaced apart from bottom surface 32 of first blind scratch 61 or may be in contact with bottom surface 32 of first blind scratch 61. Both ends of fifth dislocation 22 are exposed to upper surface 31 of first blind scratch 61. In other words, both ends of fifth dislocation 22 are in contact with upper surface 31 of first blind scratch 61.

As shown in FIG. 11, fifth dislocation 22 and first blind scratch 61 constitute a second region 42. Second region 42 constitutes a part of first main surface 1. Second region 42 is composed of fifth dislocation 22 exposed on first main surface 1 and upper surface 31 of first blind scratch 61.

As shown in FIG. 12, the length of fifth dislocation 22 in the direction perpendicular to first main surface 1 is fourth length D2. The lower limit of fourth length D2 is not particularly limited, and may be, for example, 0.1 nm or more or 1 nm or more. The upper limit of fourth length D2 is not particularly limited, and may be, for example, 10 μm or less or 1 μm or less.

As shown in FIG. 12, fourth length D2 may be less than first thickness D1, more than first thickness D1, or equal to first thickness D1. As another aspect, a part of fifth dislocation 22 may protrude to the outside of first blind scratch 61. In this case, fifth dislocation 22 is in contact with bottom surface 32.

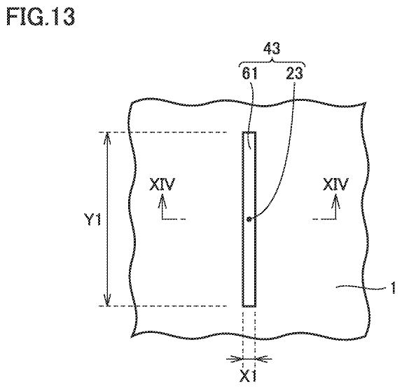

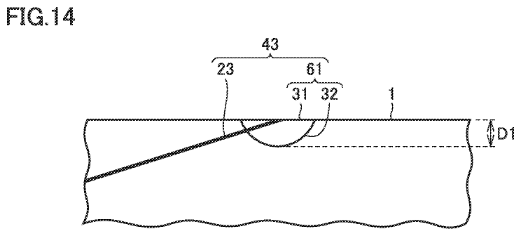

FIG. 13 is an enlarged plan view of region XIII of FIG. 1. FIG. 14 is a schematic cross-sectional view taken along line XIV-XIV of FIG. 13. The cross-section shown in FIG. 14 is perpendicular to first main surface 1. As shown in FIG. 14, sixth dislocation 23 penetrates bottom surface 32 of first blind scratch 61. Sixth dislocation 23 is exposed on upper surface 31 of first blind scratch 61. In other words, sixth dislocation 23 is in contact with each of upper surface 31 and bottom surface 32. Sixth dislocation 23 is stuck into first blind scratch 61.

As shown in FIG. 13, first blind scratch 61 into which sixth dislocation 23 is stuck constitutes a third region 43. Third region 43 constitutes a part of first main surface 1. Third region 43 is composed of sixth dislocation 23 exposed on first main surface 1 and upper surface 31 of first blind scratch 61.

As shown in FIG. 14, most of sixth dislocation 23 is located outside first blind scratch 61. As shown in FIG. 14, in the direction parallel to the basal plane, the length of the portion of sixth dislocation 23 located outside first blind scratch 61 may be longer than the length of the portion of sixth dislocation 23 located inside first blind scratch 61. As shown in FIG. 13, when viewed in the direction perpendicular to first main surface 1, the end portion of sixth dislocation 23 exposed to first main surface 1 may be surrounded by the outer edge of first blind scratch 61.

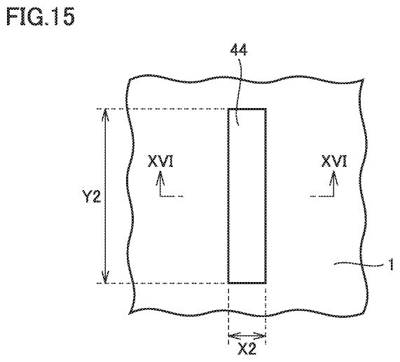

FIG. 15 is an enlarged plan view of region XV of FIG. 1. As shown in FIG. 15, silicon carbide substrate 100 may include scratch 44. Scratch 44 is a recessed portion formed in first main surface 1 by, for example, abrading a portion of silicon carbide substrate 100 with abrasive grains. When viewed in a direction perpendicular to first main surface 1, scratch 44 extends linearly. In other words, when viewed in a direction perpendicular to first main surface 1, scratch 44 has a linear shape. The linear shape may be a straight line shape or a curved line shape. When viewed in a direction perpendicular to first main surface 1, the length (a second length Y2) of scratch 44 in the longitudinal direction is, for example, 100 μm or more. When scratch 44 has a curved shape, the length (second length Y2) of scratch 44 in the longitudinal direction is a length obtained by extending the curved scratch in a straight line. The direction in which scratch 44 extends may be first direction 101, second direction 102, or a direction that is inclined with respect to each of first direction 101 and second direction 102. When scratch 44 is curved, the direction in which scratch 44 extends is a tangential direction of scratch 44. The direction in which scratch 44 extends is not particularly limited.

When viewed in the direction perpendicular to first main surface 1, the lower limit of the length of scratch 44 in the longitudinal direction (second length Y2) is not particularly limited, but may be, for example, 10 times or more or 50 times or more the width of scratch 44 in the lateral direction (a second width X2). When viewed in the direction perpendicular to first main surface 1, the upper limit of the length (second length Y2) of scratch 44 in the longitudinal direction is not particularly limited, but may be, for example, 1000 times or less or 500 times or less the width (second width X2) of scratch 44 in the lateral direction. Second length Y2 may be longer than first length Y1. Second width X2 may be more than first width XL.

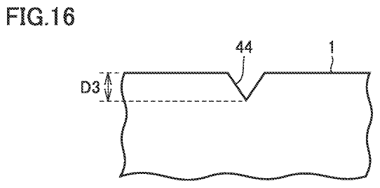

FIG. 16 is a schematic cross-sectional view taken along line XVI-XVI of FIG. 15. The cross section shown in FIG. 16 is perpendicular to first main surface 1. In cross-sectional view, scratch 44 may be, for example, V-shaped. As shown in FIG. 15, in a cross section perpendicular to the longitudinal direction of scratch 44, the width of scratch 44 may monotonically decrease with increasing distance from first main surface 1.

As shown in FIG. 16, the depth of scratch 44 in the direction perpendicular to first main surface 1 is a third depth D3. The lower limit of third depth D3 is not particularly limited, and may be, for example, 0.1 nm or more, or 1 nm or more. The upper limit of third depth D3 is not particularly limited, and may be, for example, 2000 nm or less or 1000 nm or less. Third depth D3 may be more than first thickness D1.

Next, the area density of a second defect 82 will be described. Second defect 82 consists of first basal plane dislocation 10 and second basal plane dislocation 20.

The area density of second defects 82 is determined using, for example, molten potassium hydroxide (KOH). Specifically, first main surface 1 of silicon carbide substrate 100 is etched by molten KOH. Thus, a silicon carbide region in the vicinity of second defect 82 (first basal plane dislocation 10 and second basal plane dislocation 20) exposed on first main surface 1 is etched to form an etch pit on first main surface 1. A value obtained by dividing the number of etch pits formed on first main surface 1 by the measured area of first main surface 1 corresponds to the area density of second defects 82 in first main surface 1. The temperature of the KOH melt is, for example, about 500 to 550° C. The etching time is about 5 to 10 minutes. After etching, first main surface 1 is observed using a Nomarski differential interference microscope.

When silicon carbide substrate 100 includes a threading screw dislocation and a threading edge dislocation in addition to the basal plane dislocation, silicon carbide regions near the threading screw dislocation and the threading edge dislocation exposed to first main surface 1 are also etched. Etch pits caused by basal plane dislocation are distinguished from etch pits caused by threading screw dislocation and etch pits caused by threading edge dislocation by the following method.

The etch pits caused by basal plane dislocation have an elliptical planar shape. The etch pits caused by threading screw dislocation have a round or hexagonal planar shape and a large pit size. The etch pits caused by threading edge dislocation have a round or hexagonal planar shape and a small pit size. In this evaluation method, the threading mixed dislocation is also evaluated as an etch pit similar to the threading screw dislocation, but the threading mixed dislocation is also included in the threading screw dislocation.

In silicon carbide substrate 100 according to the embodiment of the present disclosure, the area density of second defects 82 is, for example, 1000/cm² or less. The upper limit of the area density of second defects 82 is not particularly limited, and may be, for example, 500/cm² or less or 250/cm² or less. The lower limit of the area density of second defects 82 is not particularly limited, and may be, for example, 1/cm² or more, or 10/cm² or more.

Next, the area density of first defects 81 will be described. First defect 81 consists of first basal plane dislocation 10, second basal plane dislocation 20, first blind scratch 61, and second blind scratch 62.

The area density of first defects 81 is determined by observing first main surface 1 with a mirror electron microscope. Details of the mirror electron microscope will be described later. First defect 81 is a value obtained by dividing the number of first defects 81 by the measurement area of first main surface 1. Basal plane dislocation and blind scratches can be identified by mirror electron microscopy. Specifically, the number of first defects 81 is the sum of the number of first basal plane dislocations 10, the number of first regions 41, the number of second regions 42, the number of third regions 43, and the number of second blind scratches 62. The number of first basal plane dislocations 10 is the sum of the number of first dislocations 11, the number of second dislocations 12, and the number of third dislocations 13. Second basal plane dislocation 20 is in contact with first blind scratch 61. Therefore, a set of second basal plane dislocation 20 and first blind scratch 61 is counted as one first defect 81.

In silicon carbide substrate 100 according to the embodiment of the present disclosure, the area density of first defects 81 may be, for example, 400/cm² or less. The upper limit of the area density of first defects 81 is not particularly limited, and may be, for example, 380/cm² or less or 360/cm² or less. The lower limit of the area density of first defects 81 is not particularly limited, and may be, for example, 100/cm² or more or 200/cm² or more.

In silicon carbide substrate 100 according to the embodiment of the present disclosure, the area density of second blind scratches 62 may be, for example, 140/cm² or less. The upper limit of the area density of second blind scratches 62 is not particularly limited, and may be, for example, 120/cm² or less or 100/cm² or less. The lower limit of the area density of second blind scratches 62 is not particularly limited, and may be, for example, 0.01/cm² or more, or 0.1/cm² or more.

In silicon carbide substrate 100 according to the embodiment of the present disclosure, a value obtained by dividing an area density of first blind scratch 61 and second blind scratch 62 by an area density of second defect 82 may be 0.6 or less. The lower limit of the value obtained by dividing the area density of first blind scratch 61 and second blind scratch 62 by the area density of second defect 82 is not particularly limited, and may be, for example, 0.01 or more or 0.1 or more. The upper limit of the value obtained by dividing the area density of first blind scratch 61 and second blind scratch 62 by the area density of second defect 82 is not particularly limited, and may be, for example, 0.5 or less or 0.4 or less. The area density of first blind scratches 61 and second blind scratches 62 is a value obtained by dividing the sum of the number of first blind scratches 61 and the number of second blind scratches 62 by the measurement area of first main surface 1. The number of each of first blind scratch 61 and second blind scratch 62 is specified by a mirror electron microscope.

In silicon carbide substrate 100 according to the embodiment of the present disclosure, the area density of second defects 82 may be, for example, 400/cm² or less. The upper limit of the area density of second defects 82 is not particularly limited, and may be, for example, 350/cm² or less or 300/cm² or less. The lower limit of the area density of second defects 82 is not particularly limited, and may be, for example, 1/cm² or more, or 10/cm² or more.

In silicon carbide substrate 100 according to the embodiment of the present disclosure, a value obtained by dividing the area density of first defects 81 by the area density of second defects 82 is more than 0.9 and less than 1.2. The lower limit of the value obtained by dividing the area density of first defects 81 by the area density of second defects 82 is not particularly limited, but may be more than 0.94 or more than 1.0, for example. The upper limit of the value obtained by dividing the area density of first defects 81 by the area density of second defects 82 is not particularly limited, but may be less than 1.5 or less than 1.2, for example.

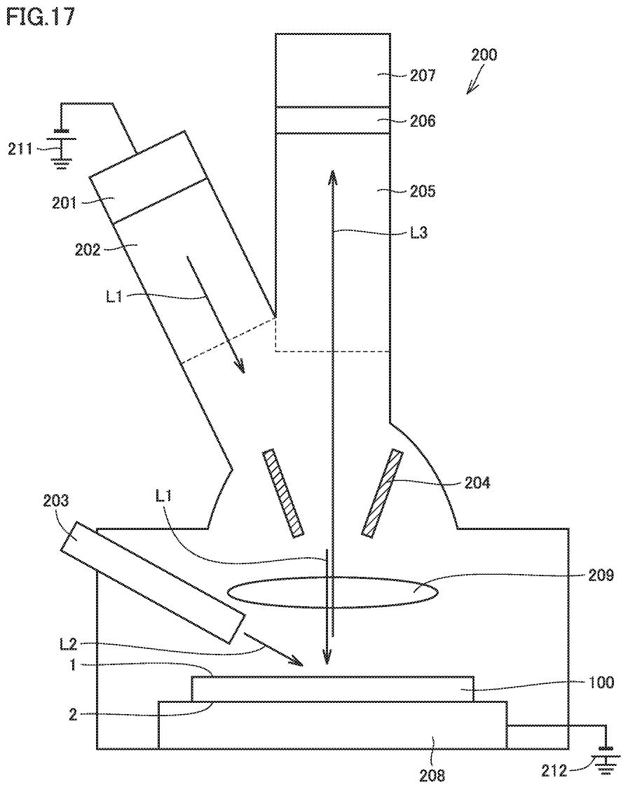

Next, a configuration of the mirror electron microscope will be described. FIG. 17 is a schematic diagram showing a configuration of a mirror electron microscope. As shown in FIG. 17, a mirror electron microscope 200 mainly includes a first power supply 211, an electron gun 201, a first electron lens 202, an ultraviolet irradiation unit 203, a separator 204, a second electron lens 205, a fluorescent screen 206, an imaging device 207, an electrostatic lens 209, a second power supply 212, and a substrate holding unit 208.

Electron gun 201 is an electron source that emits an electron beam. Electron gun 201 is connected to first power supply 211. An acceleration voltage is applied to electron gun 201 by first power supply 211. First electron lens 202 is disposed adjacent to electron gun 201. First electron lens 202 converges the electron beam. Silicon carbide substrate 100 is disposed on substrate holding unit 208. Electrostatic lens 209 is disposed above substrate holding unit 208.

The electron beam emitted by electron gun 201 passes through first electron lens 202 and electrostatic lens 209. Electrostatic lens 209 converts the electron beam converged by first electron lens 202 into a bundle of parallel electron beams. Thus, first main surface 1 of silicon carbide substrate 100 is irradiated with a bundle of parallel electron beams.

Substrate holding unit 208 is connected to second power supply 212. On first main surface 1 of silicon carbide substrate 100, a negative voltage substantially equal to the acceleration voltage of electron gun 201 is applied by second power supply 212. The irradiated electron beam is decelerated before reaching first main surface 1 of silicon carbide substrate 100. The electron beam is reversed in the vicinity of first main surface 1 without colliding with first main surface 1. Thereafter, it moves away from first main surface 1.

Second electron lens 205 is disposed between fluorescent screen 206 and separator 204. The electron beam returned from first main surface 1 passes through separator 204 and is directed to second electron lens 205. The electron beam is converged by second electron lens 205 and reaches fluorescent screen 206. Imaging device 207 captures an image (mirror electron image) formed on fluorescent screen 206. Separator 204 separates the optical path of the electron beam directed to silicon carbide substrate 100 from the optical path of the electron beam returned from silicon carbide substrate 100.

Ultraviolet irradiation unit 203 applies ultraviolet rays toward first main surface 1 of silicon carbide substrate 100. The applied ultraviolet rays have energy equal to or greater than the band gap of silicon carbide. The wavelengths of ultraviolet rays are, for example, 365 nm. When silicon carbide substrate 100 is irradiated with ultraviolet rays, each of first basal plane dislocation 10, second basal plane dislocation 20, first blind scratch 61, and second blind scratch 62 is charged.

Next, a method for measuring the area density of first defects 81 will be described. The area density of first defects 81 is determined using mirror electron microscope 200. Mirror electron microscope 200 is, for example, a mirror electron inspection device (Mirelis VM1000) manufactured by Hitachi High-Tech Technology Corporation. First, silicon carbide substrate 100 is placed on substrate holding unit 208. Second main surface 2 of silicon carbide substrate 100 faces substrate holding unit 208. First main surface 1 of silicon carbide substrate 100 faces electrostatic lens 209.

The electron beam emitted by electron gun 201 passes through first electron lens 202, separator 204, and electrostatic lens 209, and is applied onto first main surface 1 of silicon carbide substrate 100. The acceleration voltage applied to electron gun 201 is, for example, 5 eV. The electron beam (an applied electron beam L1) applied to first main surface 1 is reversed in the vicinity of first main surface 1 without colliding with first main surface 1. The electron beam (an inverted electron beam L3) returned from first main surface 1 passes through separator 204 and is converged by second electron lens 205 to reach fluorescent screen 206. The image (mirror electron image) formed on fluorescent screen 206 is captured by imaging device 207.

The ultraviolet irradiation unit applies ultraviolet rays L2 toward first main surface 1 of silicon carbide substrate 100. Each of first basal plane dislocation 10, second basal plane dislocation 20, first blind scratch 61, and second blind scratch 62 is charged by the application of ultraviolet rays L2. When the conductivity type of silicon carbide substrate 100 is n-type, each of first basal plane dislocation 10, second basal plane dislocation 20, first blind scratch 61, and second blind scratch 62 is negatively charged. In other words, each of first basal plane dislocation 10, second basal plane dislocation 20, first blind scratch 61, and second blind scratch 62 is excited by ultraviolet rays L2.

When first main surface 1 is irradiated with ultraviolet rays L2, each of second dislocation 12, fifth dislocation 22, first blind scratch 61, and second blind scratch 62 can be clearly specified. On the other hand, when first main surface 1 is not irradiated with ultraviolet rays L2, each of second dislocation 12, fifth dislocation 22, first blind scratch 61, and second blind scratch 62 can hardly be identified. Note that scratch 44 can be identified both in the case where first main surface 1 is irradiated with ultraviolet rays L2 and in the case where first main surface 1 is not irradiated with ultraviolet rays L2. When viewed in a direction perpendicular to first main surface 1, scratch 44 appears to be linear.

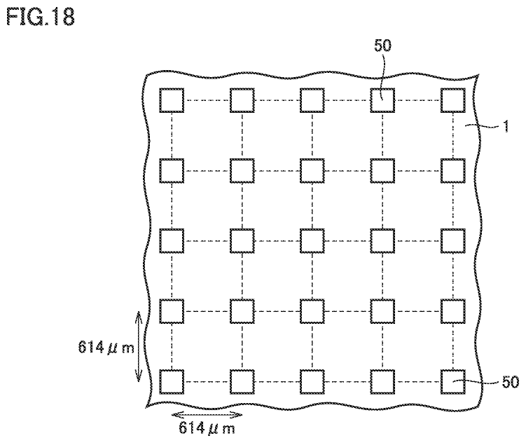

FIG. 18 is a schematic diagram showing an imaging location of a mirror electron image. By moving substrate holding unit 208 in a direction parallel to first main surface 1, a mirror electron image can be captured on the whole of first main surface 1 of silicon carbide substrate 100. As shown in FIG. 18, the position of a measurement region 50 of the mirror electron image is lattice-shaped. Measurement regions 50 each have a square shape with a side of 80 μm, for example. The interval between two adjacent measurement regions 50 is, for example, 614 sm. The maximum diameter of silicon carbide substrate 100 is, for example, 6 inches. Mirror electron images are captured at 37,952 locations on first main surface 1. As described above, the area density of first defects 81 may be determined under the condition that the interval between measurement regions 50 in first main surface 1 measured with the mirror electron microscope is 614 μm, and measurement regions 50 each have a square shape with each side of 80 μm.

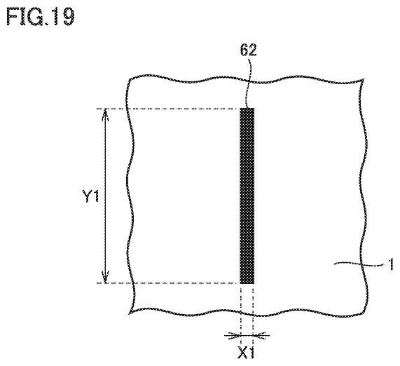

FIG. 19 is a schematic diagram showing a mirror electron image of a second blind scratch. As shown in FIG. 19, the areas of the blind scratches (first blind scratch 61 and second blind scratch 62) are displayed darker than the areas around the blind scratches. The region of the blind scratch is negatively charged, for example. In the vicinity of the negatively charged region, the equipotential surface bulges. The density of the electron beam decreases over the blind scratch. As a result, in the mirror electron image, the region of the blind scratch is darker than the region around the blind scratch.

As shown in FIG. 19, in the embodiment of the present disclosure, a region in which the width in the lateral direction (first width X1) was 0.5 μm to 5 μm, the length in the longitudinal direction (first length Y1) was 10 μm or more, and which was darker than the surrounding region was determined as the blind scratch (second blind scratch 62).

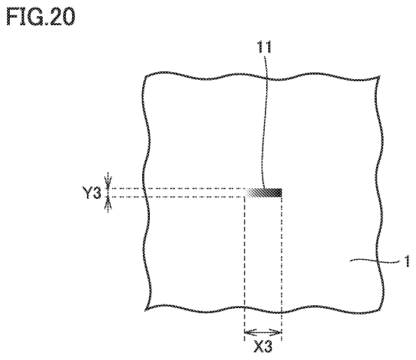

FIG. 20 is a schematic diagram showing mirror electron images of first dislocation 11 and third dislocation 13. As shown in FIG. 20, the region of the basal plane dislocation is displayed darker than the region around the basal plane dislocation. The region of basal plane dislocation is negatively charged. In the vicinity of the negatively charged region, the equipotential surface bulges. Above the basal plane dislocation, the electron beam density decreases. As a result, in the mirror electron image, the region of the basal plane dislocation is darker than the region around the basal plane dislocation.

As shown in FIG. 4, one end of the basal plane dislocation (first dislocation 11) is exposed to first main surface 1, but most of the basal plane dislocation is located inside silicon carbide substrate 100. The portion of the basal plane dislocation exposed to first main surface 1 is displayed particularly dark. As shown in FIG. 20, as the distance in the depth direction between first main surface 1 and the basal plane dislocation increases, the basal plane dislocation is displayed brighter. The brightness of the mirror electronic image changes monotonically along the direction in which the basal plane dislocation extends. In other words, the mirror electron image of basal plane dislocation is a tailed line.

As shown in FIG. 20, in the embodiment of the present disclosure, a region in which the width in the longitudinal direction (a third width X3) was 10 μm to 30 μm, the length in the lateral direction (a third length Y3) was 0.3 μm to 5 μm, and the gradation changed in the longitudinal direction was determined as a basal plane dislocation (first dislocation 11 and third dislocation 13). The determination criterion of third dislocation 13 is the same as the determination criterion of first dislocation 11.

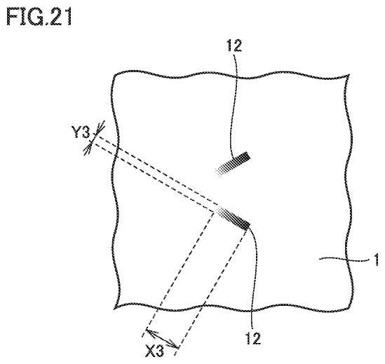

FIG. 21 is a schematic diagram showing a mirror electron image of second dislocation 12. As shown in FIG. 5, both ends of the basal plane dislocation (second dislocation 12) are exposed to first main surface 1, but most of the basal plane dislocation is located inside silicon carbide substrate 100. As shown in FIG. 21, as the distance in the depth direction between first main surface 1 and the basal plane dislocation increases, the basal plane dislocation is displayed brighter. When viewed in a direction perpendicular to first main surface 1, each of the two basal plane dislocations is inclined such that the interval between the two basal plane dislocations changes monotonically.

As shown in FIG. 21, in the embodiment of the present disclosure, when the width in the longitudinal direction (third width X3) was 10 μm to 30 μm, the length in the lateral direction (third length Y3) was 0.3 μm and to 5 μm, and there was a pair of regions where the gradation changed in the longitudinal direction, the region was determined to be basal plane dislocation (second dislocation 12).

The mirror electron image of each of fourth dislocation 21 and sixth dislocation 23 is a composite of the mirror electron image shown in FIG. 19 and the mirror electron image shown in FIG. 20. Similarly, the mirror electron image of fifth dislocation 22 is a composite of the mirror electron image shown in FIG. 19 and the mirror electron image shown in FIG. 21.

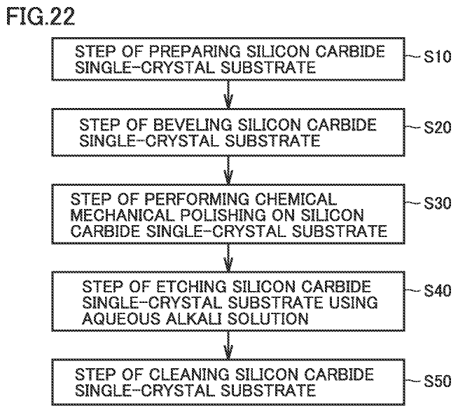

Next, a method of manufacturing silicon carbide substrate 100 according to the embodiment of the present disclosure will be described. FIG. 22 is a flow diagram schematically showing a method of manufacturing silicon carbide substrate 100 according to the embodiment of the present disclosure.

As shown in FIG. 22, the method of manufacturing silicon carbide substrate 100 according to the embodiment of the present disclosure mainly includes a step (S10) of preparing a silicon carbide single-crystal substrate, a step (S20) of beveling the silicon carbide single-crystal substrate, a step (S30) of performing chemical mechanical polishing on the silicon carbide single-crystal substrate, a step (S40) of etching the silicon carbide single-crystal substrate using an aqueous alkali solution, and a step (S50) of cleaning the silicon carbide single-crystal substrate.

First, the step (S10) of preparing a silicon carbide single-crystal substrate is performed. In particular, ingot composed of silicon carbide single crystal of polytype 4H is formed by sublimation method, for example. After the ingot is shaped, the ingot is sliced by a wire saw device. Thus, a silicon carbide single-crystal substrate 110 is cut out from the ingot.

Silicon carbide single-crystal substrate 110 is composed of hexagonal silicon carbide of polytype 4H. Silicon carbide single-crystal substrate 110 has first main surface 1 and second main surface 2 opposite to first main surface 1. First main surface 1 is, for example, a plane off by 4° or less in the <11-20> direction with respect to the {0001} plane. Specifically, first main surface 1 is, for example, a plane off by an angle of about 4° or less with respect to the (0001) plane. Second main surface 2 is, for example, a plane off by an angle of about 4° or less with respect to the (000-1) plane.

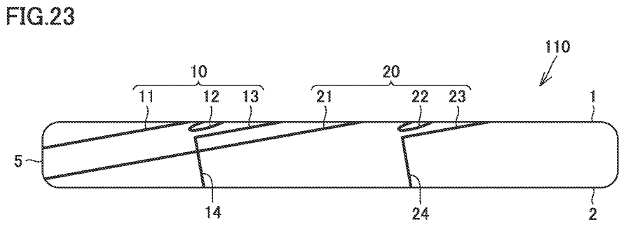

FIG. 23 is a schematic cross-sectional view showing preparing silicon carbide single-crystal substrate 110. As shown in FIG. 23, silicon carbide single-crystal substrate 110 has first main surface 1, second main surface 2, first basal plane dislocation 10, and second basal plane dislocation 20. First basal plane dislocation 10 includes first dislocation 11, second dislocation 12, and third dislocation 13. Second basal plane dislocation 20 has fourth dislocation 21, fifth dislocation 22, and sixth dislocation 23. At this time, second basal plane dislocation 20 may not be in contact with first blind scratch 61. Thus, silicon carbide single-crystal substrate 110 having first main surface 1 and second main surface 2 is prepared.

Next, the step (S20) of beveling the single-crystal silicon carbide substrate is performed. Specifically, polishing is performed on outer peripheral surface 5 of silicon carbide single-crystal substrate 110. As a result, corners of silicon carbide single-crystal substrate 110 are rounded. As a result, outer peripheral surface 5 of silicon carbide single-crystal substrate 110 is formed to be convex outward.

Next, rough polishing is performed on the single-crystal silicon carbide substrate. Specifically, each of first main surface 1 and second main surface 2 is polished by the slurry. The slurry contains, for example, diamond abrasive grains. The diamond abrasive grains have a diameter of 1 μm to 3 μm, for example. Thus, silicon carbide single-crystal substrate 110 is roughly polished on each of first main surface 1 and second main surface 2.

Next, the step (S30) of performing chemical mechanical polishing on the single-crystal silicon carbide substrate is performed. Specifically, chemical mechanical polishing is performed on silicon carbide single-crystal substrate 110 using a polishing liquid. The polishing liquid contains, for example, abrasive grains and an oxidizing agent. The abrasive grains are, for example, colloidal silica. The average grain size of the abrasive grains is, for example, 20 nm. The oxidizing agent is, for example, hydrogen peroxide solution, permanganate, nitrate, hypochlorite or the like. The polishing liquid is, for example, DSC-0902 manufactured by Fujimi Inc.

First main surface 1 of silicon carbide single-crystal substrate 110 is disposed to face the polishing cloth. The polishing cloth is, for example, nonwoven cloth manufactured by Nitta Haas (SUBA800) or suede manufactured by Fujibo (G804 W). A polishing solution containing abrasive grains is supplied between first main surface 1 and the polishing cloth. Single-crystal silicon carbide substrate 110 is attached to the head. The rotational speed of the head is, for example, 60 rpm. The rotational speed of the surface plate provided with the polishing cloth is, for example, 60 rpm. The machining surface pressure is, for example, 500 g/cm². The polishing amount of silicon carbide single-crystal substrate 110 is, for example, 1 μm or more.

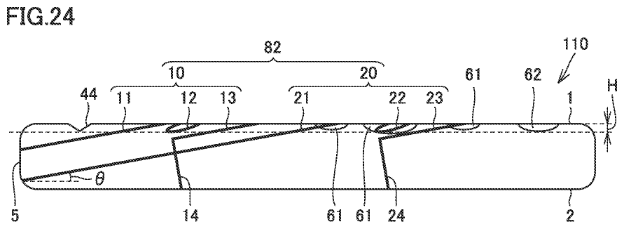

FIG. 24 is a schematic cross-sectional view showing the structure of silicon carbide single-crystal substrate 110 after the step of performing chemical mechanical polishing on silicon carbide single-crystal substrate 110. As shown in FIG. 24, first blind scratch 61 and second blind scratch 62 are formed on first main surface 1 by chemical mechanical polishing. Thicknesses H of each of first blind scratch 61 and second blind scratch 62 is 0.1 μm to 1 μm, for example. A region in which basal plane dislocation is present is more susceptible to polishing damage than a normal crystal portion. As a result, a blind scratch is likely to occur in a portion where the basal plane dislocation is exposed to first main surface 1.

As shown in FIG. 24, first blind scratch 61 and second blind scratch 62 are formed on first main surface 1 by chemical mechanical polishing. First blind scratch 61 is formed in contact with second basal plane dislocation 20. Second blind scratch 62 is formed spaced apart from each of first basal plane dislocation 10 and second basal plane dislocation 20. Scratch 44 may be formed on first main surface 1.

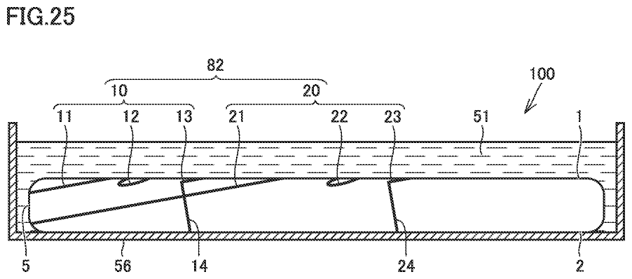

Next, the step (S40) of etching the single-crystal silicon carbide substrate using an aqueous alkali solution is performed. FIG. 25 is a schematic cross-sectional view showing a step of etching silicon carbide single-crystal substrate 110 using an aqueous alkali solution. As shown in FIG. 25, silicon carbide single-crystal substrate 110 is immersed in an etching solution 51. Etching solution 51 is contained in a vessel 56. A portion of silicon carbide single-crystal substrate 110 is etched by etching solution 51.

Etching solution 51 includes an aqueous alkali solution. The aqueous alkali solution is, for example, aqueous potassium hydroxide solution (KOH) or aqueous sodium hydroxide solution (NaOH). The temperature of etching solution 51 is 70° C. or higher. As described above, silicon carbide single-crystal substrate 110 is etched using solution 51 under the temperature condition of 70° C. or higher.

The lower limit of the temperature of etching solution 51 is not particularly limited, and may be, for example, 73° C. or higher or 76° C. or higher. The temperature of solution 51 may be, for example, 100° C. or lower. The upper limit of the temperature of etching solution 51 is not particularly limited, and may be, for example, 97° C. or lower or 93° C. or lower.

Etching solution 51 contains, for example, potassium hydroxide and water. In etching solution 51, the mass ratio of potassium hydroxide to water is, for example, 2:3. Etching solution 51 may further include an oxidizing agent that does not cause an oxidation-reduction reaction with the aqueous alkali solution. The oxidizing agent is, for example, a hydrogen peroxide solution. The oxidizing agent may be, for example, potassium permanganate.

Etching solution 51 may contain potassium hydroxide, a hydrogen peroxide solution, and water. In etching solution 51, the mass ratio of potassium hydroxide, hydrogen peroxide solution, and water is, for example, 4:1:5. As the hydrogen peroxide solution, for example, a hydrogen peroxide solution having a mass percentage concentration of 30% can be used. The hydrogen peroxide solution is introduced immediately before the etching process.

As shown in FIG. 25, in the step (S40) of etching the silicon carbide single-crystal substrate using the aqueous alkali solution, first blind scratches 61 and second blind scratches 62 are etched by etching solution 51. Thus, first blind scratches 61 and second blind scratches 62 are removed from silicon carbide single-crystal substrate 110. Some of first blind scratches 61 may remain on first main surface 1. Some of second blind scratches 62 may remain on first main surface 1. Almost all of first dislocation 11, second dislocation 12, third dislocation 13, fourth dislocation 21, fifth dislocation 22, and sixth dislocation 23 remain in first main surface 1. First threading dislocation 14 and second threading dislocation 24 remain inside silicon carbide single-crystal substrate 110.

Next, the step (S50) of cleaning silicon carbide single-crystal substrate 110 is performed. In the step (S50) of cleaning silicon carbide single-crystal substrate 110, silicon carbide single-crystal substrate 110 is cleaned with water. As a result, etching solution 51 adhering to silicon carbide single-crystal substrate 110 is washed away by water. As described above, silicon carbide substrate 100 according to the embodiment of the present disclosure is manufactured (see FIGS. 1 and 25).

Next, operational effects of silicon carbide substrate 100 and the method of manufacturing silicon carbide substrate 100 according to the embodiment of the present disclosure will be described.

In main surface 1 of silicon carbide single-crystal substrate 110, a blind scratch (polishing damage) may generate due to polishing. When the silicon carbide epitaxial layer is formed on the blind scratches, minute stacking faults are likely to be formed in the silicon carbide epitaxial layer due to the blind scratches. As a result, the surface roughness of the main surface of the silicon carbide epitaxial layer may deteriorate.

As a method for removing the blind scratches (first blind scratch 61 and second blind scratch 62) formed on main surface 1 of silicon carbide single-crystal substrate 110, it is conceivable to etch silicon carbide single-crystal substrate 110 with molten KOH. However, when silicon carbide single-crystal substrate 110 is etched by molten KOH, pits are formed in first basal plane dislocation 10 and second basal plane dislocation 20 exposed to main surface 1 of silicon carbide single-crystal substrate 110. In this case, the surface roughness of main surface 1 of silicon carbide single-crystal substrate 110 is deteriorated.

As a result of intensive studies on measures for removing blind scratches without forming pits on main surface 1 of silicon carbide single-crystal substrate 110, the present inventors have obtained the following findings. Specifically, silicon carbide single-crystal substrate 110 was etched using an aqueous alkali solution instead of molten KOH. Specifically, silicon carbide single-crystal substrate 110 is etched using a solution 51 including an aqueous alkali solution under a temperature condition of 70° C. or higher. Thus, first blind scratch 61, second blind scratch 62, second dislocation 12, and fifth dislocation 22 can be removed without forming a pit on first main surface 1 of silicon carbide single-crystal substrate 110. As a result, deterioration of the surface roughness of the main surface of the silicon carbide epitaxial layer formed on first main surface 1 of silicon carbide substrate 100 can be suppressed.

In addition, according to the method of manufacturing silicon carbide substrate 100 according to the embodiment of the present disclosure, solution 51 may further include an oxidizing agent that does not cause an oxidation-reduction reaction with the aqueous alkali solution. This makes it possible to more effectively remove first blind scratch 61 and second blind scratch 62. As a result, deterioration of the surface roughness of the main surface of the silicon carbide epitaxial layer formed on first main surface 1 of silicon carbide substrate 100 can be further suppressed.

In silicon carbide substrate 100 according to the embodiment of the present disclosure, a value obtained by dividing the area density of first defects 81 by the area density of second defects 82 is larger than 0.9 and smaller than 1.2. This makes it possible to reduce the number of first blind scratches 61 and second blind scratches 62. As a result, deterioration of the surface roughness of the main surface of the silicon carbide epitaxial layer formed on first main surface 1 of silicon carbide substrate 100 can be suppressed.

### EXAMPLES

(Sample Preparation)

First, silicon carbide substrates 100 according to samples 1 to 3 were prepared. Silicon carbide substrate 100 according to the sample 1 was taken as a comparative example. Silicon carbide substrates 100 according to the samples 2 and 3 were examples. In the step (S40) of manufacturing silicon carbide substrates 100 according to the samples 2 and 3, the step (S40) of etching the silicon carbide single-crystal substrate using an aqueous alkali solution was performed. Meanwhile, in manufacturing silicon carbide substrate 100 according to the sample 1, the step (S40) of etching silicon carbide single-crystal substrate 110 using the aqueous alkali solution was not performed.

In manufacturing silicon carbide substrate 100 according to the sample 2, etching solution 51 contained potassium hydroxide and water. In etching solution 51, the mass ratio of potassium hydroxide to water was 2:3. The temperature of etching solution 51 was set to 80° C.

In manufacturing silicon carbide substrate 100 according to the sample 3, etching solution 51 contained potassium hydroxide, a hydrogen peroxide solution, and water. In etching solution 51, the mass ratio of potassium hydroxide, the hydrogen peroxide solution, and water was 4:1:5. The temperature of etching solution 51 was 90° C.

### (Evaluation Method)

The area density of first defects 81 in first main surface 1 of silicon carbide substrate 100 according to each of the samples 1 to 3 was measured using mirror electron microscope 200. The measurement method is as described above. To be specific, the area density of first defect 81 was measured using a mirror electronic inspection device (Mirelis VM1000) manufactured by Hitachi High-Tech Technology Corporation. The wavelengths of the ultraviolet rays were 365 nm. Measurement regions 50 of the mirror electron image were positioned in a lattice pattern. Measurement region 50 was a square shape with a side of 80 μm. The interval between two adjacent measurement regions 50 was 614 μm. Mirror electron images were captured at 37952 locations on first main surface 1. First defect 81 detected using mirror electron microscope 200 consists of first basal plane dislocation 10, second basal plane dislocation 20, first blind scratch 61, and second blind scratch 62.

Next, second defect 82 in first main surface 1 of silicon carbide substrate 100 according to each of the samples 1 to 3 was measured using molten KOH. The measurement method is as described above. Specifically, the temperature of the KOH melt was set to 525° C. The etching time was about 7.5 minutes. After etching, first main surface 1 is observed using a Nomarski differential interference microscope. The magnification of the Nomarski differential interference microscope was 200 times. Second defect 82 detected using molten KOH consists of first basal plane dislocation 10 and second basal plane dislocation 20.

Next, silicon carbide substrates 100 according to the samples 1 to 3 different from the samples used in the above measurement were prepared. A silicon carbide epitaxial layer was formed on first main surface 1 of silicon carbide substrate 100 according to samples 1 to 3. After the silicon carbide epitaxial layer was formed, haze, which is an index of surface roughness, was measured on the surface of the silicon carbide epitaxial layer. The haze is an index indicating the degree of surface roughness. As the surface roughness decreases, the haze value decreases. The haze of a perfectly flat surface is zero. The unit of haze is dimensionless.

The haze was measured using a WASAVI series “SICA 6X” manufactured by Lasertec corporation. To be specific, the surface of the silicon carbide epitaxial substrate was irradiated with light having wavelengths 546 nm from light sources such as mercury-xenon lamps, and reflected light of the light was observed by light receiving elements. The difference between the brightness of a certain pixel in the observed image and the brightness of pixels around the certain pixel was quantified.

The haze is obtained by quantifying a difference in brightness between a plurality of pixels included in an observed image by the following method. To be specific, the maximum haze value of a rectangular region obtained by dividing one observation field of view of 1.8 mm+0.2 mm square into 64 regions was derived. One observation field of view includes an imaging region of 1024×1024 pixels. The maximum haze value was derived as an absolute value obtained by calculating edge intensities in the horizontal direction and the vertical direction of the observation field with a Sobel filter. By the above-described procedure, the maximum haze value of each observation visual field was observed in the entire surface of the silicon carbide epitaxial layer. The average value of the maximum haze values in the respective observation fields was taken as the haze value at the surface of the silicon carbide epitaxial layer.

Further, an arithmetic average roughness Sa was measured on the surface of the silicon carbide epitaxial layer. The arithmetic average roughness Sa is a three dimensional surface quality parameter defined by International Standard ISO25178. The arithmetic average roughness Sa was measured using a white light interferometric microscope or the like. The measurement area of the white light interferometric microscope was 255 μm square. The measurement positions for measuring the arithmetic average roughness Sa were total nine points. The points were in the center and eight locations equally arranged in the circumferential direction at a distance of 30 mm from the center toward the periphery on each surface. The average value of the measurement data was defined as Sa (ave.). The maximum value of the measurement data was defined as Sa (max).

### (Evaluation Results)

TABLE 1

| | | Sample 1 | Sample 2 | Sample 3 |
|---|---|---|---|---|
| Condition for Etching | Solution | None | KOH + H₂O | KOH + H₂O₂ + H₂O |
| with Aqueous Alkali | Mass Concentration | — | KOH:2 | KOH:4 |
| Solution | | | H₂0:3 | H₂O₂:1 |
| | | | | H₂O:5 |
| | Temperature [° C.] | — | 80 | 90 |
| Mirror Electron | Area Density of First | 592 | 372 | 336 |
| Microscope | Defect | | | |
| | [/cm²]: (1) | | | |
| Etch Pit Method with | Area Density of Second | 315 | 324 | 352 |
| Molten KOH | Defect | | | |
| | [/cm²]: (2) | | | |
| Ratio | (1)/(2) | 1.88 | 1.15 | 0.95 |
| Surface Roughness after | Haze (ave.) | 21.61 | 20.08 | 20.06 |
| Epitaxial Growth | Sa (ave.) [nm] | 0.22 | 0.12 | 0.11 |
| | Sa (max) [nm] | 0.25 | 0.18 | 0.17 |

As shown in Table 1, the surface densities of first defects 81 in first main surface 1 of silicon carbide substrate 100 according to the samples 1 to 3 detected using mirror electron microscope 200 were 592/cm², 372/cm², and 336/cm², respectively. The surface densities of second defects 82 in first main surface 1 of silicon carbide substrate 100 according to the samples 1 to 3 detected using molten KOH were 315/cm², 324/cm², and 352/cm², respectively. That is, in first main surface 1 of silicon carbide substrate 100 according to each of the samples 1 to 3, values (ratios of blind scratch) obtained by dividing the area density of first defects 81 by the area density of second defects 82 were 1.88, 1.15, and 0.95, respectively.

As shown in the above results, the ratios of the blind scratches on first main surface 1 of silicon carbide substrate 100 according to the samples 2 and 3 were smaller than the ratio of the blind scratches on first main surface 1 of silicon carbide substrate 100 according to the sample 1. As shown in FIG. 18, each of the plurality of measurement regions 50 of mirror electron microscope 200 are separated from each other. Therefore, a mirror electron image is not observed in a region between two adjacent measurement regions 50. As a result, the area density of first defect 81 measured by the mirror electron image may be calculated to be lower than the actual area density of first defect 81.

As shown in Table 1, the haze of the surface of the silicon carbide epitaxial layer formed on first main surface 1 of silicon carbide substrate 100 according to the samples 1 to 3 was 21.61, 20.08, and 20.06, respectively. Sa (ave.) of the surface of the silicon carbide epitaxial layer formed on first main surface 1 of silicon carbide substrate 100 according to the samples 1 to 3 was 0.22 nm, 0.12 nm, and 0.11 nm, respectively. Sa (max) of the surface of the silicon carbide epitaxial layer formed on first main surface 1 of silicon carbide substrate 100 according to the samples 1 to 3 was 0.25 nm, 0.18 nm, and 0.17 nm, respectively.

As shown in the above results, the surface roughness of the silicon carbide epitaxial layer formed on first main surface 1 of silicon carbide substrate 100 according to the samples 2 and 3 was smaller than the surface roughness of the silicon carbide epitaxial layer formed on first main surface 1 of silicon carbide substrate 100 according to the sample 1.

It should be understood that the embodiments and examples disclosed herein are illustrative in all respects and are not restrictive. The scope of the present invention is defined not by the above description but by the claims, and is intended to include meanings equivalent to the claims and all modifications within the scope.

### REFERENCE SIGNS LIST

1 first main surface (main surface), 2 second main surface, 3 orientation flat, 4 arc-shaped portion, 5 outer peripheral surface, 10 first basal plane dislocation, 11 first dislocation, 12 second dislocation, 13 third dislocation, 14 first threading dislocation, 20 second basal plane dislocation, 21 fourth dislocation, 22 fifth dislocation, 23 sixth dislocation, 24 second threading dislocation, 31 upper surface, 32 bottom surface, 41 first region, 42 second region, 43 third region, 44 scratch, 50 measurement region, 51 etching solution, 56 vessel, 61 first blind scratch, 62 second blind scratch, 81 first defect, 82 second defect, 100 silicon carbide substrate, 101 first direction, 102 second direction, 110 silicon carbide single-crystal substrate, 200 mirror electron microscope, 201 electron gun, 202 first electron lens, 203 ultraviolet irradiation unit, 204 separator, 205 second electron lens, 206 fluorescent screen, 207 imaging device, 208 substrate holding unit, 209 electrostatic lens, 211 first power supply, 212 second power supply, A maximum diameter, D1 first thickness, D2 fourth length, D3 third depth, H thickness, L1 applied electron beam, L2 ultraviolet rays, L3 inverted electron beam, X1 first width, X2 second width, X3 third width, Y1 first length, Y2 second length, Y3 third length, θ off-angle

1. A silicon carbide substrate comprising:
a first main surface;
a second main surface located opposite to the first main surface; and
an outer peripheral surface contiguous to each of the first main surface and the second main surface,
wherein when a defect, in the first main surface, observed using a mirror electron microscope while irradiating the first main surface with an ultraviolet ray is a first defect and a defect, in the first main surface, observed using molten potassium hydroxide is a second defect, a value obtained by dividing an area density of the first defect by an area density of the second defect is more than 0.9 and less than 1.2,
the first defect consists of a first blind scratch, a first basal plane dislocation spaced apart from the first blind scratch, a second basal plane dislocation in contact with the first blind scratch, and a second blind scratch spaced apart from each of the first basal plane dislocation and the second basal plane dislocation, and
the second defect consists of the first basal plane dislocation and the second basal plane dislocation.

2. The silicon carbide substrate according to claim 1, wherein the area density of the first defect is determined under a condition that an interval between measurement regions in the first main surface measured with the mirror electron microscope is 614 μm, and the measurement regions each have a square shape with each side of 80 μm.

3. The silicon carbide substrate according to claim 1, wherein the area density of the second defect is 1000/cm² or less.

4. The silicon carbide substrate according to claim 3, wherein the area density of the second defect is 500/cm² or less.

5. The silicon carbide substrate according to claim 1, wherein the area density of the first defect is 400/cm² or less.

6. The silicon carbide substrate according to claim 1, wherein a value obtained by dividing an area density of the first blind scratch and the second blind scratch by the area density of the second defect is 0.6 or less.

7. A method of manufacturing a silicon carbide substrate, the method comprising:
performing chemical mechanical polishing on a silicon carbide single-crystal substrate; and
etching the silicon carbide single-crystal substrate using a solution under a temperature condition of 70° C. or higher,
wherein the solution contains an aqueous alkali solution.

8. The method of manufacturing a silicon carbide substrate according to claim 7, wherein the aqueous alkali solution is an aqueous potassium hydroxide solution or an aqueous sodium hydroxide solution.

9. The method of manufacturing a silicon carbide substrate according to claim 7, wherein the temperature condition is 100° C. or lower.

10. The method of manufacturing a silicon carbide substrate according to claim 7, wherein the solution further contains an oxidizing agent not causing an oxidation-reduction reaction with the aqueous alkali solution.

11. The method of manufacturing a silicon carbide substrate according to claim 10, wherein the oxidizing agent is a hydrogen peroxide solution.
